(19) United States
(12) Patent Application Publication
(10) Pub. No.: US 2026/0221061 A1
(43) Pub. Date: Jul. 30, 2026

(54) INSPECTION SYSTEM AND DISPLAY DEVICE

(71) Applicant: Sharp Display Technology Corporation, Kameyama City, Mie (JP)

(72) Inventors: Naoki SHIOBARA, Kameyama City, Mie (JP); Masaaki MORIYA, Kameyama City, Mie (JP); Masafumi UENO, Kameyama City, Mie (JP); Mohammad Reza KAZEMI, Kameyama City, Mie (JP); Masafumi KAWAI, Kameyama City, Mie (JP); Hiroyuki FURUKAMA, Kameyama City, Mie (JP)

(21) Appl. No.: 19/147,058

(22) PCT Filed: Jan. 11, 2023
(86) PCT No.: PCT/JP2023/000458

§ 371 Date: Jul. 10, 2025

(51) Int. Cl. G09G 3/00; G01J 1/42; G09G 3/3233

(52) U.S. Cl. CPC G09G 3/006; G01J 1/42; G09G 3/035; G09G 3/3233; G01J 2001/4252; G09G 2300/0819; G09G 2320/045; G09G 2360/145

(57) ABSTRACT

An inspection system includes: a first display region including a first EL element; a second display region including a second EL element; and a control unit controlling the first EL element and the second EL element. In an inspection mode for compensating for degradation of the first EL element, the control unit: causes the first EL element to emit light in order to operate the first EL element as a light-emitting element; causes the second EL element to stop emitting light in order to operate the second EL element as a light-receiving element; and as the second EL element receives the light emitted from the first EL element, generates a compensation parameter, for compensating for degradation of the first EL element, in accordance with a current output from the second EL element.

### TECHNICAL FIELD

An aspect of the present disclosure relates to an inspection system having an electro-luminescent (EL) element.

### BACKGROUND ART

Patent Document 1 below discloses a technique for compensating for (correcting) degradation of an EL element.

### CITATION LIST

### Patent Literature

[Patent Document 1] Japanese Unexamined Patent Application Publication No. 2012-186218

### SUMMARY

### Technical Problem

An aspect of the present disclosure sets out to compensate for degradation of an EL element using an unconventional technique.

### Solution to Problem

An inspection system according to an aspect of the present disclosure includes: a first display region including a first EL element; a second display region including a second EL element; and a control unit that controls the first EL element and the second EL element. In an inspection mode for compensating for degradation of the first EL element, the control unit: causes the first EL element to emit light in order to operate the first EL element as a light-emitting element; causes the second EL element to stop emitting light in order to operate the second EL element as a light-receiving element, and as the second EL element receives the light emitted from the first EL element; generates a compensation parameter, for compensating for degradation of the first EL element, in accordance with a current output from the second EL element.

An inspection system according to an aspect of the present disclosure includes: a first display device including a first display region including a first EL element; a second display device including a second display region including a second EL element; a first control unit that controls the first EL element; and a second control unit configured to control the second EL element. The first control unit and the second control unit are communicably connected together, and in an inspection mode for compensating for degradation of the first EL element, the first control unit causes the first EL element to emit light in order to operate the first EL element as a light-emitting element, the second control unit causes the second EL element to stop emitting light in order to operate the second EL element as a light-receiving element, and as the second EL element receives the light emitted from the first EL element, the first control unit generates a compensation parameter, for compensating for the degradation of the first EL element, in accordance with a current output from the second EL element.

A display device according to an aspect of the present disclosure includes: a first display region including a first display region including a first EL element; a second display region including a second display region including a second EL element; and a control unit that controls the first EL element and the second EL element. In an inspection mode for compensating for degradation of the first EL element, the control unit: causes the first EL element to emit light in order to operate the first EL element as a light-emitting element; causes the second EL element to stop emitting light in order to operate the second EL element as a light-receiving element; and as the second EL element receives the light emitted from the first EL element, generates a compensation parameter, for compensating for degradation of the first EL element, in accordance with a current output from the second EL element.

### Advantageous Effect of Disclosure

An aspect of the present disclosure can compensate for degradation of an EL element using an unconventional technique.

### BRIEF DESCRIPTION OF DRAWINGS

FIG. 1 is a block diagram illustrating an exemplary configuration of an inspection system of a first embodiment.

FIG. 2 illustrates an example of a display device of the first embodiment in an extended state.

FIG. 3 illustrates an example of the display device of the first embodiment in a folded state.

FIG. 4 illustrates an example of voltage-current characteristics of an EL element.

FIG. 5 is an exemplary configuration of a pixel circuit in a display region.

FIG. 6 shows various examples of inspection patterns.

FIG. 7 schematically illustrates an example of a pivot mechanism.

FIG. 8 schematically illustrates an exemplary configuration of a display device of a third embodiment.

FIG. 9 is a block diagram illustrating an exemplary configuration of an inspection system of a fourth embodiment.

FIG. 10 illustrates an example of how a first display region of a first display device and a second display region of a second display device face each other in an inspection system of a fourth embodiment.

FIG. 11 schematically illustrates an exemplary configuration of a display device of a fifth embodiment.

### DESCRIPTION OF EMBODIMENTS

### First Embodiment

A first embodiment will be described below. For convenience in description, like reference signs designate components (constituent elements) having identical functions between the first embodiment and the following embodiments. These components will not be elaborated upon repeatedly. For the sake of brevity, descriptions of known technical issues are also omitted as appropriate. The components and the numerical values described in the Description are solely examples unless otherwise contradicting. Hence, for example, positional relationships and connection relationships of the components shall not be limited to examples of the drawings unless otherwise contradicting. Furthermore, the drawings are not necessarily drawn to scale.

### Exemplary Configuration of Inspection System 100

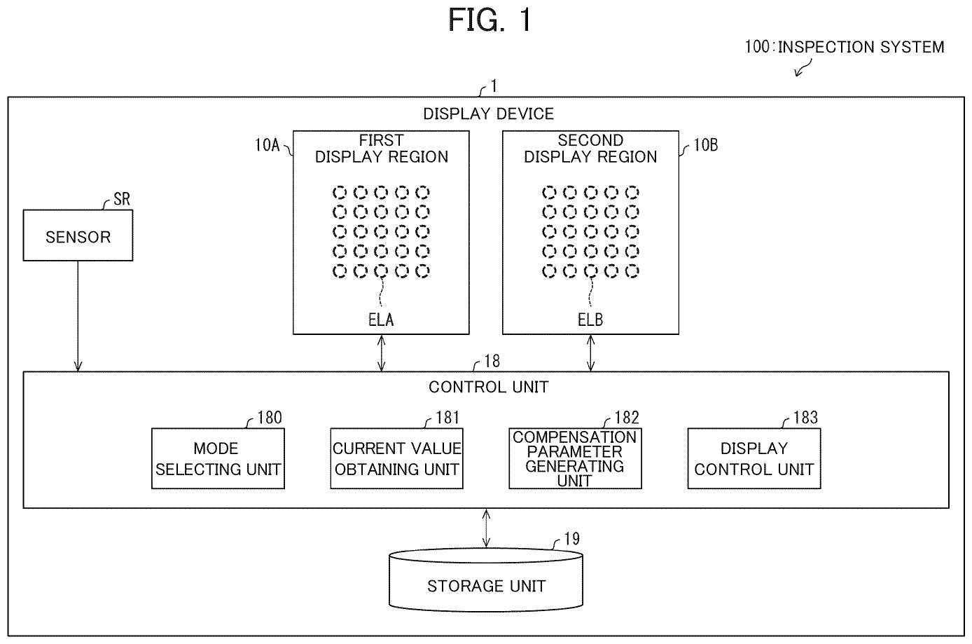

FIG. 1 is a block diagram illustrating an exemplary configuration of an inspection system 100 of the first embodiment. The inspection system 100 may have a display device 1. As illustrated in FIG. 1, the inspection system 100 includes: a first display region 10A; a second display region 10B; a control unit 18; and a storage unit 19. The inspection system 100 may further include a sensor SR.

In the first embodiment, the display device 1 is, for example, a dual-screen display device. The first embodiment exemplifies a case where the display device 1 has the first display region 10A and the second display region 10B as individual display panels. For the sake of simplicity, FIG. 1 exemplifies a case where the display device 1 also has other components of the inspection system 100.

However, as will be apparent to those skilled in the art, some components of the inspection system 100 may be provided to the display device 1. As an example, the sensor SR may be an external component of the display device 1. As another example, the control unit 18 may be an external component of the display device 1. In these cases, the display device 1 may be communicably connected to the external components.

As illustrated in FIG. 1, the first display region 10A includes a plurality of first EL elements ELA. The plurality of first EL elements ELA may be arranged vertically (longitudinally) and horizontally (transversely) in a matrix in the first display region 10A. The first display region 10A may also be referred to as a first display surface.

Similarly, the second display region 10B includes a plurality of second EL elements ELB. The plurality of second EL elements ELB may be arranged vertically (longitudinally) and horizontally (transversely) in a matrix in the second display region 10B. The second display region 10B may also be referred to as a second display surface.

As described above, the first display region 10A and the second display region 10B may have the same configuration. Hence, in the Description, the first display region 10A and the second display region 10B may be collectively referred to as a display region 10. Respective components corresponding to the first display region 10A and the second display region 10B may also be collectively referred to. Furthermore, in the Description, the first EL elements ELA and the second EL elements ELB may be collectively referred to as EL elements.

An EL element operates as a light-emitting element that emits light upon receiving an electrical input. The EL element may be a charge-injection self-luminous element. Hence, examples of the EL element can include an organic light-emitting diode (OLED) or a quantum-dot LED (QLED). Moreover, as will be described later, the EL element generates an electrical signal upon receiving light. Thus, the EL element can operate as a light-receiving element that outputs an electrical signal upon receiving light.

The control unit 18 may have centralized control of the components of the inspection system 100. Hence, for example, the control unit 18 may control the display region 10. As illustrated in FIG. 1, the control unit 18 may include: a mode selecting unit 180; a current value obtaining unit 181; a compensation parameter generating unit 182; and a display control unit 183. The control unit 18 (more specifically, the display control unit 183) may control an operating state of the EL elements. Exemplary processing of the control unit 18 will be described later. The storage unit 19 stores various data and programs to be used for the processing of the control unit 18.

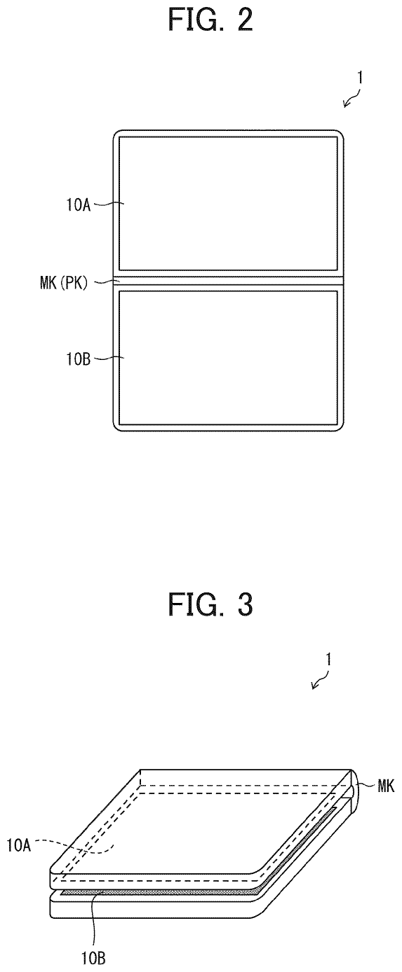

With reference to FIGS. 2 and 3, a configuration of the display device 1 will be described in more detail. The first embodiment exemplifies a flexible display device as the display device 1. More specifically, the first embodiment exemplifies a foldable display device (a display device that can be folded up) as the flexible display device. Hence, the display device 1 can be in a folded state and an extended state. FIG. 2 illustrates an example of the display device 1 in the extended state, and FIG. 3 illustrates an example the display device 1 in the folded state.

The display device 1 may include a mechanism MK for mechanically connecting the first display region 10A and the second display region 10B together. The mechanism MK may be any given mechanism as long as the mechanism MK can change a relative position of the second display region 10B in relation to the first display region 10A in order to cause the first display region 10A and the second display region 10B to face each other.

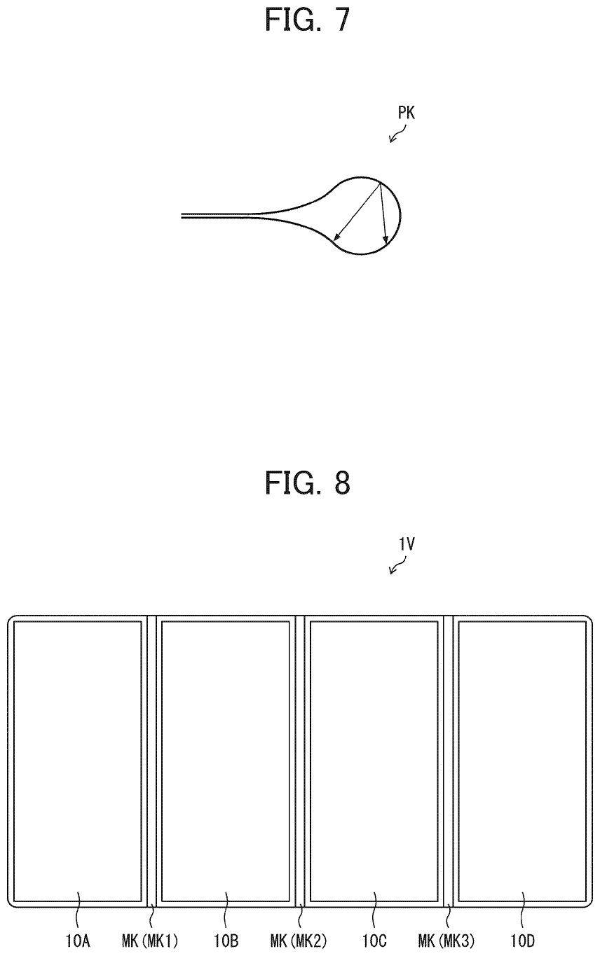

As an example, the mechanism MK may be a pivot mechanism PK (e.g., a hinge) pivotably connecting the first display region 10A and the second display region 10B together. The pivot mechanism PK allows at least one of the first display region 10A or the second display region 10B to pivot. Hence, as illustrated in FIG. 3, the first display region 10A and the second display region 10B can overlap with, and face, each other. An example of the pivot mechanism PK is illustrated in FIG. 7 as will be described later.

In the first embodiment, the sensor SR may detect that the first display region 10A and the second display region 10B have faced each other. The sensor SR may employ any given detecting technique as long as the sensor SR can detect that the first display region 10A and the second display region 10B have faced each other. As an example, the sensor SR may be a proximity sensor. In this case, the sensor SR may be provided to at least one of the first display region 10A or the second display region 10B. As another example, the sensor SR may be a camera provided outside the display device 1.

Display quality of the display region 10 could degrade as the EL elements degrade. Hence, the display region 10 is operable in different modes such as a normal mode and an inspection mode. The normal mode is a mode (an ordinary display mode) of the display region 10 for displaying an image in an ordinary manner. In the normal mode, both the first display region 10A and the second display region 10B display images in accordance with an instruction from a display control unit 183. In the example of the first embodiment, both the first display region 10A and the second display region 10B emit light in the normal mode. The Description omits descriptions for issues directed to the normal mode but irrelevant to the inspection mode.

The inspection mode is a mode of the display region 10 for compensating for degradation of the EL elements. The inspection mode generates a compensation parameter for compensating for degradation of either the first EL elements ELA in the first display region 10A or the second EL elements ELB in the second display region 10B. The Description mainly describes a case where the inspection mode generates a compensation parameter for compensating for degradation of the first EL elements ELA. Note that, as will be apparent from the description to be given later, the inspection mode does not allow a light-receiving region (e.g., the second display region 10B) to display an image. For this reason, the inspection mode may also be referred to as a special mode.

### Exemplary Sequence of Processing on Control Unit 18

The mode selecting unit 180 selects a mode of the display region 10. The mode selecting unit 180 may switch modes of the display region 10 from the normal mode to the inspection mode as soon as a predetermined first event occurs. In other words, the mode selecting unit 180 may start the inspection mode as soon as the first event occurs.

As an example, the first event may be a case where the first display region 10A and the second display region 10B face each other. Hence, the mode selecting unit 180 may start the inspection mode as soon as the first display region 10A and the second display region 10B face each other. Thus, when the sensor SR detects that the first display region 10A and the second display region 10B face each other, the mode selecting unit 180 may start the inspection mode. As another example, the mode selecting unit 180 may start the inspection mode as soon as receiving a predetermined input operation (e.g., an instructing operation to start the inspection mode) from a user.

When the mode selecting unit 180 selects the inspection mode, the display control unit 183 causes the second EL elements ELB to stop emitting light (e.g., causes the second EL elements ELB to stop driving) in order to operate the second EL elements ELB as light-receiving elements. Hence, in the inspection mode, the display control unit 183 causes the second display region 10B to operate as a light-receiving region (e.g., a light-receiving face).

In the inspection mode, the display control unit 183 drives the first EL elements ELA and causes the first EL elements ELA to emit light. In other words, in the inspection mode, the display control unit 183 causes the first EL elements ELA to operate as light-emitting elements. Hence, in the inspection mode, the display control unit 183 causes the first display region 10A to operate as a light-emitting region (e.g., a light-emitting face).

As an example, in the inspection mode, the display control unit 183 causes the first EL elements ELA to emit light so that the first display region 10A displays an inspection pattern. Data of inspection patterns may be previously stored in the storage unit 19. Examples of the inspection patterns will be described in a second embodiment later.

In the inspection mode, a portion of the light emitted from the first EL elements ELA can reach the second EL elements ELB. For example, when the first display region 10A and the second display region 10B face each other, the second EL elements ELB receive most of the light emitted from the first EL elements ELA.

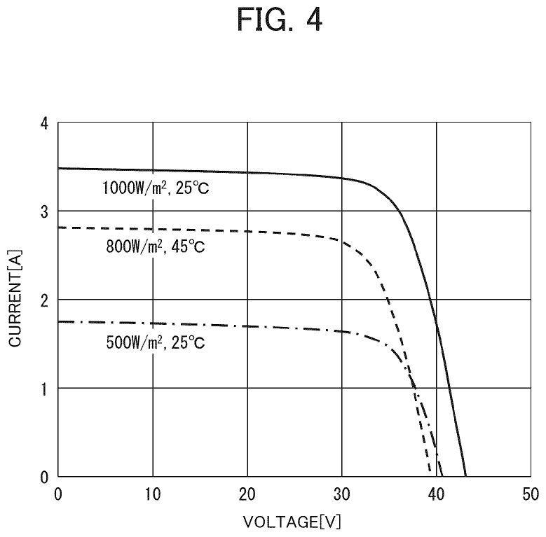

Upon receiving the light emitted from the first EL elements ELA, the second EL elements ELB generate a voltage (a photovoltage) and a current (a photocurrent) corresponding to the light. FIG. 4 is a graph showing an example of voltage (V)-current (I) characteristics of an EL element. In the graph, the horizontal axis represents voltage and the vertical axis represents current.

As illustrated in FIG. 4, the V-I characteristics of the EL element depends on luminance of light emitted to the EL element. Specifically, when Vis constant, I increases as the luminance is higher. More specifically, when V is constant, I is substantially proportional to the luminance. Hence, in the inspection mode, the luminance may be estimated in accordance with, for example, I.

Furthermore, as illustrated in FIG. 4, the V-I characteristics of the EL element depends on the temperature of the EL element. The temperature significantly affects the V-I characteristics in a region in which Vis relatively high (i.e., a region in which I is close to zero). Whereas, the temperature does not significantly affect the V-I characteristics in a region in which Vis relatively low (i.e., a region in which I is close to a maximum value). Hence, in the inspection mode, I is measured preferably while V is controlled to have a minimum value. Such a feature makes it possible to estimate the luminance while reducing the effect of the temperature. As a result, the luminance can be estimated with higher precision. In the inspection mode, Vdata and ELVSS to be described later may be set for controlling V.

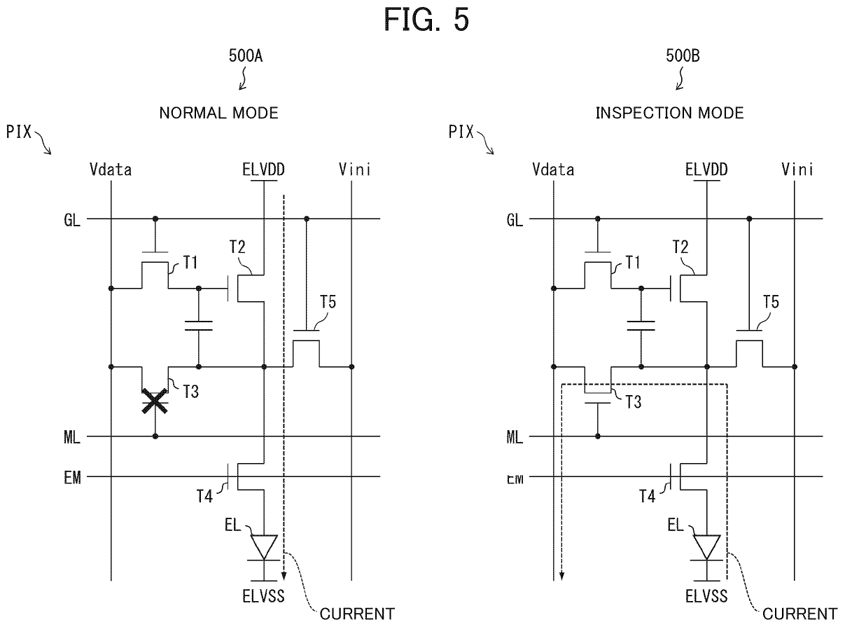

The display region 10 may have a pixel circuit PIX including an EL element. The pixel circuit PIX may measure I in the inspection mode. FIG. 5 is an exemplary configuration of the pixel circuit PIX. In FIG. 5, a reference sign 500A denotes a current flow in the normal mode, and a reference sign 500B denotes a current flow in the inspection mode. As to the pixel circuit PIX, descriptions will be omitted of circuit elements and signal lines irrelevant to the inspection mode.

As illustrated in FIG. 5, the low-level voltage ELVSS may be applied to the EL element. Then, the pixel circuit PIX may have transistors T1 to T5 to serve as switching elements. ON/OFF states of the transistors T1 to T5 may be switched by the control unit 18 (e.g., the display control unit 183).

As denoted by the reference sign 500A in FIG. 5, the normal mode sets the transistors T2 and T4 to the ON state. Hence, a high-level voltage ELVDD is applied to an anode of the EL element. Hence, the EL element emits light. Furthermore, the normal mode sets the transistor T3 to the ON state. Hence, in the normal mode, a current does not flow from a high-level voltage terminal (a terminal to which the high-level voltage ELVDD is applied) to a data signal line (a signal line to which a data signal Vdata is applied).

Whereas, as denoted by the reference sign 500B in FIG. 5, the inspection mode sets the transistor T2 to the OFF state. Hence, the high-level voltage ELVDD is not applied to the anode of the EL element. Thus, in the inspection mode, the EL element does not emit light. Then, in the inspection mode, the transistor T3 is set to the ON state. Hence, a current flows from the EL element through the transistor T3 to the data signal line. As an example, the display region 10 may include a not-shown current sensor that detects a magnitude (a value) of the current.

In the inspection mode, as the second EL elements ELB receive the light emitted from the first EL elements ELA, the compensation parameter generating unit 182 may generate a compensation parameter, for compensating for the degradation of the first EL elements ELA, in accordance with the current output from the second EL elements ELB. In order to make a distinction from a second compensation parameter to be described later, the compensation parameter for compensating for the degradation of the first EL elements ELA may be referred to as a first compensation parameter.

It can be seen that the further the first EL elements ELA degrade, the lower the luminance of the light is when the light is emitted from the first EL elements ELA. Hence, it can be seen that the further the first EL elements ELA degrade, the smaller the current is when flowing from the second EL elements ELB to the data signal line in the inspection mode. Thus, the current value detected by the current sensor is seen as one of indexes indicating to what degree the first EL elements ELA degrade.

Hence, for example, the current value obtaining unit 181 may obtain from the current sensor the current value detected by the current sensor. Then, the compensation parameter generating unit 182 may generate a compensation parameter in accordance with the current value obtained by the current value obtaining unit 181 (hereinafter referred to as an “obtained current value”).

For example, in the inspection mode, the compensation parameter generating unit 182 may derive (e.g., estimate) luminance of light, emitted from the first EL elements ELA, in accordance with the current flowing through the EL elements. Thus, for example, the compensation parameter generating unit 182 may derive the luminance in accordance with the obtained current value. Next, the compensation parameter generating unit 182 may generate a compensation parameter in accordance with the derived luminance.

For example, the storage unit 19 may previously store a table indicating the corresponding relationship between I and luminance described above with reference to FIG. 4. In this case, the compensation parameter generating unit 182 can derive the luminance from the obtained current value, using the table. Next, the compensation parameter generating unit 182 may calculate, as a compensation parameter, a difference between (i) a previously set ideal current value (a current value assumed when no degradation occurs to the first EL elements ELA) and (ii) the obtained current value.

It can be seen that the further the first EL elements ELA degrade, the more apparent a deviation is between the ideal current value and the obtained current value. Thus, it can be seen that the further the first EL elements ELA degrade, the larger the compensation parameter is. Hence, the compensation parameter may be set as a parameter indicating a degree of deviation between the ideal current value and the obtained current value. Note that, as will be apparent to those skilled in the art, the method for setting the compensation parameter shall not be limited to the above example.

The compensation parameter generating unit 182 may store the generated compensation parameter in the storage unit 19. The mode selecting unit 180 may switch modes of the display region 10 from the inspection mode to the normal mode as soon as a predetermined second event, which is different from the first event, occurs. In other words, the mode selecting unit 180 may finish the inspection mode as soon as the second event occurs.

As an example, the second event may be a case where the generation of the compensation parameter ends. Hence, for example, as soon as the compensation parameter generating unit 182 stores the compensation parameter in the storage unit 19, the mode selecting unit 180 may finish the inspection mode. As another example, the mode selecting unit 180 may finish the inspection mode as soon as receiving a predetermined input operation (e.g., an instructing operation to finish the inspection mode) from the user.

After the end of the inspection mode, in the normal mode, the display control unit 183 may obtain video data (more specifically, a video input signal). Then, the display control unit 183 may correct the video input signal in accordance with the compensation parameter.

For example, the display control unit 183 may correct a signal value of the video input signal in accordance with the compensation parameter. In other words, in accordance with the compensation parameter, the display control unit 183 may correct gradation levels of pixels in each of the frames included in a video. Next, in accordance with the corrected input video signal, the display control unit 183 may generate a first drive signal for driving the first EL elements ELA. Thus, in the normal mode, the first display region 10A can display a video with the degradation of the first EL elements ELA compensated for.

### Advantageous Effects

Various techniques have been proposed to detect degradation of EL elements. However, with a method for estimating to what degree the EL elements degrade without using luminance of light emitted from the EL elements, it is not always easy to appropriately estimate the degree of degradation. Hence, Patent Document 1 discloses a concept that the display device is provided with an optical sensor that measures luminance of light emitted from the EL elements. However, the optical sensor disclosed in Patent Document 1 is an additional component for the display device, and, therefore, the display device could have problems of complexity in configuration and increase in costs.

Whereas, the inventors of the disclosure have found out a novel concept that “some of a plurality of EL elements is also used as light-receiving elements”. The inspection system 100 of the first embodiment is created in accordance with the concept. The inspection system 100 causes the second EL elements ELB to operate as light-receiving elements in the inspection mode, thereby successfully measuring luminance of the first EL elements ELA serving as light-emitting elements. As a result, the inspection system 100 can appropriately compensate for degradation of the first EL elements ELA without an additional optical sensor. As can be seen, the inspection system 100 can compensate for degradation of the EL elements, using an unconventional technique.

Furthermore, as can be seen, the inspection system 100 can start the inspection mode as soon as the first display region 10A and the second display region 10B face each other. Thus, for example, when the user is assumed not to watch the video in the normal mode, the inspection system 100 can start the inspection mode. Such a feature can reduce the risk that the user might feel inconvenient when the inspection mode is carried out. For example, the inspection mode can be completed during a period in which the user carries the display device 1 in the folded state in his or her bag (e.g., during commuting time to work or school).

In addition, in a case where the first display region 10A and the second display region 10B face each other, ambient light is less likely to be incident on the second EL elements ELB. Such a feature makes it possible to more precisely estimate to what degree the first EL elements ELA degrade. As a result, the inspection system 100 can compensate for the degradation of the first EL elements ELA more appropriately.

### Supplementary Remarks on Inspection Mode

The first embodiment describes an exemplary case where the inspection mode involves operating the first display region 10A as a light-emitting region and the second display region 10B as a light-receiving region, in order to compensate for the degradation of the first EL elements ELA. However, as will be apparent to those skilled in the art, in one aspect of the present disclosure, the EL elements whose degradation is to be compensated for may be the second EL elements ELB. Hence, the light-emitting region may be the second display region 10B, and the light-receiving region may be the first display region 10A.

Thus, for example, in the inspection mode, the display control unit 183 may cause the first EL elements ELA to stop emitting light in order to operate the first EL elements ELA as light-receiving elements. In this case, in the inspection mode, the display control unit 183 causes the second EL elements ELB to operate as light-emitting elements.

In this case, as the first EL elements ELA receive light emitted from the second EL elements ELB, the current value obtaining unit 181 obtains a value of a current output from the first EL elements ELA. Then, the compensation parameter generating unit 182 generates a compensation parameter, for compensating for degradation of the second EL elements ELB, in accordance with an obtained current value (i.e., a value of a current flowing from the first EL elements ELA to the data signal line in the inspection mode). In order to make a distinction from the first compensation parameter described above, the compensation parameter for compensating for the degradation of the second EL elements ELB may be referred to as the second compensation parameter.

After the inspection mode ends, in the normal mode, the display control unit 183 may correct the video input signal in accordance with the second compensation parameter. Next, in accordance with the corrected input video signal, the display control unit 183 may generate a second drive signal for driving the second EL elements ELB. Thus, in the normal mode, the second display region 10B can display a video with the degradation of the second EL elements ELB compensated for.

As can be seen, the inspection system 100 can compensate for degradation of both the first EL elements ELA and the second EL elements ELB. Hence, for example, after the end of an inspection mode for compensating for the degradation of the first EL elements ELA (i.e., a first inspection mode for convenience sake), the inspection system 100 may immediately start an inspection mode for compensating for the degradation of the second EL elements ELB (i.e., a second inspection mode for convenience sake).

The control unit 18 (e.g., the mode selecting unit 180) may alternately switch between the first inspection mode and the second inspection mode in a period in which the first display region 10A and the second display region 10B face each other. Such a feature makes it possible to more reliably obtain both the first compensation parameter and the second compensation parameter.

### Second Embodiment

In the inspection mode, a light-emitting region (e.g., the first display region 10A) may display any given image. That is, in the inspection mode, the light-emitting elements (e.g., the first EL elements ELA) may emit light on any given light-emission pattern. However, if an excessively large number of light-emitting elements emit light, the light emitted from the light-emitting elements diffuses considerably. In this case, the diffused light is incident in large amount on the light-receiving elements (e.g., the second EL elements ELB). That is why the light-receiving elements could have difficulty in appropriately measuring luminance distribution of the light-emitting elements. As a result, it could be difficult to appropriately measure to what degree the light-emitting elements degrade.

Hence, in the inspection mode, only a relatively small number of the light-emitting elements are preferably driven to emit light. Such a feature can reduce the risk that the diffused light might be incident on the light-receiving elements, thereby making it possible to estimate more appropriately to what degree the light-emitting elements degrade. Hence, as can be seen in the inspection mode, the display control unit 183 causes the first EL elements ELA to emit light so that a predetermined inspection pattern is displayed on the first display region 10A. The inspection pattern man be any given inspection pattern as long as a locally bright region is found in the first display region 10A. The second embodiment describes examples of inspection patterns.

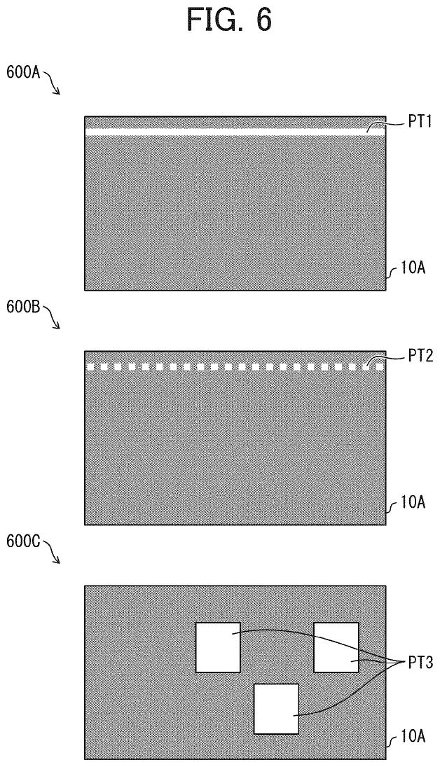

FIG. 6 shows various examples of inspection patterns. As an example, a reference sign 600A in FIG. 6 denotes that the inspection pattern may be a linearly pattern PT1 in one dimension. The linearly pattern PT1 may extend in, for example, a horizontal direction of the first display region 10A. Hence, in the example of the reference sign 600A, the display control unit 183 causes all of the first EL elements ELA that belong to any given one row in the first display region 10A to emit light. Whereas, the display control unit 183 causes the other first EL elements ELA to stop emitting light.

As another example, a reference sign 600B in FIG. 6 denotes that the inspection pattern may be a dotted-line pattern PT2 in one dimension. Hence, in the example of the reference sign 600B, the display control unit 183 causes some of the first EL elements ELA that belong to any given one row in the first display region 10A to emit light.

Specifically, the display control unit 183 controls the first EL elements ELA to emit light so that, among the plurality of first EL elements ELA that belong to the one row, neighboring first EL elements ELA are controlled not to simultaneously emit light. The number of the first EL elements ELA in the light-emitting state is smaller in the dotted-line pattern PT2 than in the linearly pattern PT1. Hence, the dotted-line pattern PT2 can further reduce the diffused light than the linearly pattern PT1.

As yet another example, a reference sign 600C in FIG. 6 denotes that the inspection pattern may be an island-shaped pattern PT2 having a plurality of bright regions scattered in two dimensions. The two-dimensional island-shaped pattern PT3 can display the bright regions over wider area in the first display region 10A than the inspection patterns in one dimension (e.g., the linearly pattern PT1 and the dotted-line pattern PT2 described above). Hence, compared with the one-dimensional inspection patterns, the two-dimensional island-shaped pattern PT3 can reduce time for compensation for the degradation of all the first EL elements ELA.

### Modification

In the inspection mode, a plurality of the light-emission patterns may be used in combination. For example, the display control unit 183 may first cause all the first EL elements ELA to emit light. In this case, the current value obtaining unit 181 obtains an obtained current value for all the first EL elements ELA. Then, the current value obtaining unit 181 may generate a map (an obtained current value map) indicating spatial distribution of the obtained current values. Thanks to the obtained current value map, a region indicating remarkable degradation of the first display region 10A can be roughly identified.

Next, the display control unit 183 may set, as a region of interest, the region identified with the obtained current value map to have the remarkable degradation. Then, the display control unit 183 may cause only the first EL elements ELA corresponding to the region of interest to emit light. In this case, the current value obtaining unit 181 obtains an obtained current value for the first EL elements ELA corresponding to the region of interest. Such a feature makes it possible to more specifically estimate to what degree the first EL elements ELA degrade in the region of interest. Such a series of processing is suitable when, for example, the first display region 10A is large in size.

Furthermore, in order to reduce an effect of the diffusion of light emitted from the light-emitting elements, the display region 10 may be provided with an anti-reflection member (e.g., a polarizing plate).

### Modification

The light-emitting region (e.g., the first display region 10A) and the light-receiving region (e.g., the second display region 10B) may be operated manually by the user to face each other. Note that, depending on how the user manually operates, misalignment might be caused between the first display region 10A and the second display region 10B. Ambient light is more likely to be incident on the light-receiving elements (e.g., the second EL elements ELB) in a non-overlapping region between the first display region 10A and the second display region 10B than in an overlapping region between the first display region 10A and the second display region 10B.

Hence, the sensor SR may detect the misalignment between the first display region 10A and the second display region 10B. For example, as the sensor SR, either a distance sensor or a camera may be used to detect the misalignment. If the misalignment is detected by the sensor SR, the control unit 18 may notify the user of the misalignment. For example, if the misalignment is detected by the sensor SR, the control unit 18 may drive a not-shown audio output device (e.g., a speaker) of the inspection system 100 and encourage the user to correct the misalignment.

As another example, the sensor SR may detect an amount of misalignment between the first display region 10A and the second display region 10B in a certain direction (e.g., in a longitudinal direction of the first display region 10A). In this case, in the inspection mode, the compensation parameter generating unit 182 may correct a compensation parameter in accordance with the amount of misalignment. Hence, even if the misalignment cannot be solved between the first display region 10A and the second display region 10B, the above feature makes it possible to obtain a more appropriate compensation parameter.

Furthermore, as yet another example, in accordance with the amount of misalignment detected by the sensor SR, the control unit 18 may identify the non-overlapping region between the first display region 10A and the second display region 10B. In this case, in the inspection mode, the display control unit 183 may cause the first EL elements ELA that belong to the non-overlapping region in the first display region 10A to stop emitting light. Then, only for the overlapping region in the second display region 10B, the compensation parameter generating unit 182 may generate a compensation parameter in accordance with an obtained current value. Hence, even if the misalignment cannot be solved between the first display region 10A and the second display region 10B, the above feature can reduce an effect of ambient light on the compensation parameter.

### Modification

FIG. 7 schematically illustrates an example of the pivot mechanism PK described above. The pivot mechanism PK in the example of FIG. 7 is a hinge whose outer shape is shaped into a water droplet. The hinge may be used, for example, to reduce thickness of the display device 1 in the folded state. Note that, as can be understood from FIG. 7, light is likely to diffuse inside the hinge. As a result, for example, in the vicinity of the hinge, light from the plurality of light-emitting elements (e.g., the first EL elements ELA) is likely to be incident on one light-receiving element (e.g., a second EL element ELB) because of the diffusion of light inside the hinge.

Hence, in the inspection mode, processing to be executed in the vicinity of the mechanism MK in the light-receiving region (e.g., the second display region 10B) may be different from processing to be executed in a region other than the vicinity of the mechanism MK in the second display region 10B. For example, the compensation parameter generating unit 182 may correct a compensation parameter for a second EL element ELB positioned in the vicinity of the mechanism MK. A correction amount of the compensation parameter may be previously set according to, for example, characteristics of the light scattering in the mechanism MK.

### Third Embodiment

In the first embodiment, the display device 1 is, for example, a dual-screen display device. However, as will be apparent to those skilled in the art, in one aspect of the present disclosure, the number of the display regions in the display device shall not be limited to the above number. FIG. 8 schematically illustrates an exemplary configuration of a display device 1V of a third embodiment. The display device 1V is another example of the flexible display device. FIG. 8 illustrates an example of the display device 1V in the extended state.

As illustrated in FIG. 8, the display device 1V may further include: a third display region 10C; and a fourth display region 10D. In the example of FIG. 8, the third display region 10C and the fourth display region 10D may also be respectively referred to as a third display surface and a fourth display surface. The third display region 10C includes a not-shown plurality of third EL elements. The fourth display region 10C includes a not-shown plurality of fourth EL elements.

In the display device 1V, any given two of the four display regions 10 may face each other. Hence, for example, two adjacent display regions 10 in FIG. 8 may be mechanically connected together by the mechanism MK. In the example of FIG. 8, a mechanism MK for connecting the first display region 10A and the second display region 10B together is referred to as an MK1, a mechanism MK for connecting the second display region 10B and the third display region 10C together is referred to as an MK2, and a mechanism MK for connecting the third display region 10C and the fourth display region 10D together is referred to as an MK3.

In the display device 1V, the MK changes a relative position of one display region 10 (e.g., the fourth display region 10D) in relation to another display region 10 (e.g., the first display region 10A) so that the other display region 10 (e.g., the first display region 10A) and the one display region 10 (the fourth display region 10D) can face each other.

Hence, in the display device 1V, the control unit 18 may start the inspection mode as soon as any given two of the four display regions 10 face each other. Then, the control unit 18 may operate one of the two facing display regions 10 as a light-emitting region and the other as a light-receiving region. Thus, in an inspection mode for compensating for degradation of a third EL element; that is, a third inspection mode, the third EL element operates as a light-emitting element so that a compensation parameter for compensating for degradation of the third EL element; that is, a third compensation parameter, can be generated. Furthermore, in an inspection mode for compensating for degradation of a fourth EL element; that is, a fourth inspection mode, the fourth EL element operates as a light-emitting element so that a compensation parameter for compensating for degradation of the fourth EL element; that is, a fourth compensation parameter, can be generated.

### Fourth Embodiment

A display device according to an aspect of the present disclosure may be a non-flexible display device. Furthermore, a display device according to an aspect of the present disclosure may be a single-screen display device. Hence, a single-screen non-flexible display device may be used to implement an inspection system according to an aspect of the present disclosure.

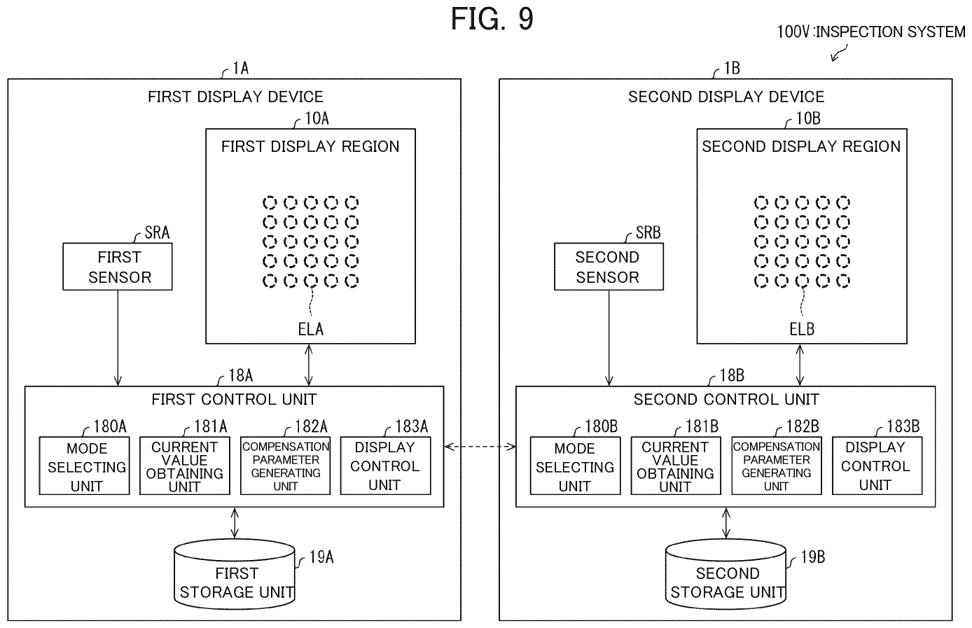

FIG. 9 is a block diagram illustrating an exemplary configuration of an inspection system 100V of a fourth embodiment. The inspection system 100V may include a first display device 1A and a second display device 1B instead of the display device 1 of the inspection system 100. Each of the first display device 1A and the second display device 1B may be a single-screen non-flexible display device (e.g., a single-screen tablet). The first display device 1A includes the first display region 10A. The second display device 1B includes the second display region 10B. As can be seen in an inspection system according to an aspect of the present disclosure, the first display region 10A and the second display region 10B do not have to be included in a single display device.

As illustrated in FIG. 9, in the inspection system 100V, a control unit (a first control unit 18A) for controlling the first display region 10A and a control unit (a second control unit 18B) for controlling the second display region 10B may be separate components. Hence, for example, the first display device 1A may include the first control unit 18A, and the second display device 1B may include the second control unit 18B. As can be seen, a control unit according to an aspect of the present disclosure does not have to be a single control unit.

The first control unit 18A and the second control unit 18B may be communicably connected together. Thus, the first control unit 18A and the second control unit 18B can cooperate (e.g., operate together in a synchronized manner), and respectively operate the first EL elements ELA and the second EL elements ELB. Hence, the first control unit 18A and the second control unit 18B cooperate to generate, in the inspection mode, a compensation parameter for compensating for degradation of the light-emitting elements.

In the example of FIG. 9, a suffix A is added to each of the components corresponding to the first control unit 18A, and a suffix B is added to each of the components corresponding to the second control unit 18B. As seen in FIG. 9, the first display device 1A may include a first storage unit 19A, and the second display device 1B may include a second storage unit 19B. Furthermore, as seen in FIG. 9, the inspection system 100V may include, as separate components, a sensor (a first sensor SRA) for detecting a state of the first display region 10A and a sensor (a second sensor SRB) for detecting a state of the second display region 10B. Hence, for example, the first display device 1A may include the first sensor SRA, and the second display device 1B may include the second sensor SRB.

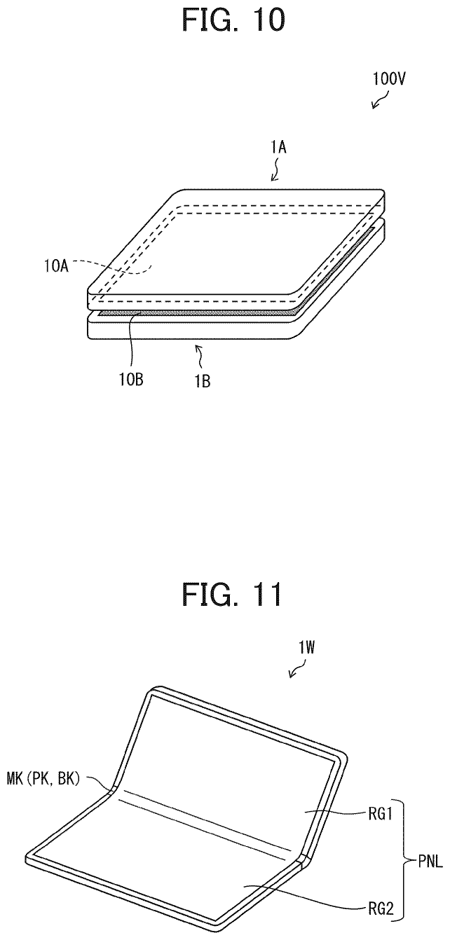

FIG. 10 illustrates an example of how the first display region 10A of the first display device 1A and the second display region 10B of the second display device 1B face each other in the inspection system 100V. A user of the inspection system 100V can change, for example, a position of at least one of the first display device 1A or the second display device 1B so that the first display region 10A and the second display region 10B can face each other. Hence, the first control unit 18A and the second control unit 18B may start the inspection mode as soon as the first display region 10A and the second display region 10B face each other.

Described below is an example of processing in the first inspection mode in the fourth embodiment. First, the first control unit 18A may cause the first EL elements ELA to emit light in order to operate the first EL elements ELA as light-emitting elements. Next, the second control unit 18B may cause the second EL elements ELB to stop emitting light in order to operate the second EL elements ELB as light-receiving elements. Then, as the second EL elements ELB receive the light emitted from the first EL elements ELA, the first control unit 18A may generate the first compensation parameter, for compensating for degradation of the first EL elements ELA, in accordance with a current output from the second EL elements ELB.

Described below is an example of processing in the second inspection mode of the fourth embodiment. First, the second control unit 18B may cause the second EL elements ELB to emit light in order to operate the second EL elements ELB as light-emitting elements. Next, the first control unit 18A may cause the first EL elements ELA to stop emitting light in order to operate the first EL elements ELA as light-receiving elements. Then, as the first EL elements ELA receive the light emitted from the second EL elements ELB, the second control unit 18B may generate the second compensation parameter, for compensating for degradation of the second EL elements ELB, in accordance with a current output from the first EL elements ELA.

In the fourth embodiment, the first control unit 18A and the second control unit 18B may alternately switch between the first inspection mode and the second inspection mode in a period in which the first display region 10A and the second display region 10B face each other. When communicably connected together, the first control unit 18A and the second control unit 18B can conduct such coordination therebetween.

### Fifth Embodiment

A flexible display device according to an aspect of the present disclosure may be a single-screen display device. FIG. 11 schematically illustrates an exemplary configuration of a display device 1W of a fifth embodiment. The display device 1W may have a single display panel PNL. The display panel PNL may be formed of a flexible material. The display panel PNL may have: a first display region RG1 including the first EL elements ELA; and a second display region RG2 including the second EL elements ELB (i.e., in FIG. 11, the first EL elements ELA and the second EL elements ELB are not shown).

As clearly seen in FIG. 11, depending on a relative position of the second display region RG2 in relation to the first display region RG1, for example, light emitted from the first EL elements ELA can be incident on the second EL elements ELB. Hence, in the inspection mode, the control unit 18 in the display device 1W may operate, for example, the first EL elements ELA as light-emitting elements and the second EL elements ELB as light-receiving elements. Thus, the display device 1W can also generate a compensation parameter for correcting degradation of light-emitting elements.

As illustrated in FIG. 11, the display device 1W may include the mechanism MK for mechanically connecting the first display region RG1 and the second display region RG2 together. In the display device 1W, the mechanism MK changes a relative position of the second display region RG2 in relation to the first display region RG1 so that the first display region 10A and the second display region 10B can face each other.

As an example, the display device 1W may be a foldable display device. Hence, for example, the mechanism MK may be the pivot mechanism PK that rotatably connects the first display region RG1 and the second display region RG2 together. In this case, the pivot mechanism PK allows at least one of the first display region RG1 or the second display region RG2 to pivot so that the first display region RG1 and the second display region RG2 can overlap with, and face, each other.

As another example, the display device 1W may be a bendable display device (a foldable display device). In this case, the display panel PNL may be formed of a film-like flexible material. Hence, for example, the mechanism MK may be a folding mechanism BK foldably connecting the first display region RG1 and the second display region RG2 together. In this case, the folding mechanism BK folds at least one of the first display region RG1 or the second display region RG2 so that the first display region RG1 and the second display region RG2 can face each other.

As can be seen, the display device 1W can cause the first display region RG1 and the second display region RG2 to face each other. Hence, for example, in the display device 1W, the control unit 18 may start the inspection mode as soon as the first display region RG1 and the second display region RG2 face each other.

The fifth embodiment describes an exemplary case where the display device 1W has a single display panel, and the single display panel has a first display region and a second display region. However, as described in the first to fourth embodiments, the first display region and the second display region of the display device according to an aspect of the present disclosure may be respective individual display panels. Hence, in the display device according to an aspect of the present disclosure, the first display region and the second display region may be at least one display panel. The above description of the display device according to one aspect of the present disclosure also applies to an inspection system according to one aspect of the present disclosure.

### Exemplary Implementation in the Form of Software

Functions of the inspection systems 100 to 100V and the display devices 1 to 1W (hereinafter collectively referred to as a “device”) are implemented in a form of a program for causing a computer to function as the device and as the control blocks (in particular, the units included in the control unit 18, the first control unit 18A, and the second control unit 18B) of the device.

In this case, the device includes a computer having at least one control device (e.g., a processor) and at least one storage device (e.g., a memory), both of which serve as hardware for executing the above program. The control device and the storage device execute the program to achieve the functions described in the above embodiments.

The program may be recorded on one or a plurality of non-transitory computer-readable recording media. Such recording media may or may not be included in the above device. In the latter case, the program may be supplied to the device through any given wired or wireless transmission medium.

Furthermore, the functions of the control blocks can be partially or entirely implemented in the form of a logic circuit. For example, an integrated circuit forming a logic circuit functioning as the control blocks is also included in the scope of one aspect of the present disclosure. Otherwise, the functions of the control blocks can be implemented in a form of, for example, a quantum computer.

The processing described in the above embodiments may be executed by artificial intelligence (AI). In this case, the AI may operate on the control device or on another device (e.g., an edge computer or a cloud server).

### ADDITIONAL REMARKS

An aspect of the present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the aspect of the present disclosure. Moreover, the technical aspects disclosed in each embodiment may be combined together to achieve a new technical feature.

1. An inspection system, comprising:
a first display region including a first EL element;
a second display region including a second EL element; and
a control unit configured to control the first EL element and the second EL element,
wherein, in an inspection mode for compensating for degradation of the first EL element, the control unit:
causes the first EL element to emit light in order to operate the first EL element as a light-emitting element;
causes the second EL element to stop emitting light in order to operate the second EL element as a light-receiving element; and
as the second EL element receives the light emitted from the first EL element, generates a compensation parameter, for compensating for degradation of the first EL element, in accordance with a current output from the second EL element.

2. The inspection system according to claim 1,
wherein the control unit starts the inspection mode as soon as the first display region and the second display region face each other.

3. The inspection system according to claim 1, further comprising
a sensor configured to detect that the first display region and the second display region have faced each other.

4. The inspection system according to claim 1,
wherein, in the inspection mode, the control unit:
derives luminance of the light, emitted from the first EL element, in accordance with the current output from the second EL element; and
generates the compensation parameter in accordance with the derived luminance.

5. The inspection system according to claim 1,
wherein, in the inspection mode, the control unit causes the first EL element to emit light so that the first display region displays an inspection pattern.

6. The inspection system according to claim 5,
wherein the inspection pattern is a linearly pattern in one dimension.

7. The inspection system according to claim 5,
wherein the inspection pattern is a dotted-line pattern in one dimension.

8. The inspection system according to claim 5,
wherein the inspection pattern is an island-shaped pattern having a plurality of bright regions scattered in two dimensions.

9. The inspection system according to claim 1,
wherein the inspection mode for compensating for the degradation of the first EL element is referred to as a first inspection mode,
an inspection mode for compensating for degradation of the second EL element is referred to as a second inspection mode,
the compensation parameter for compensating for the degradation of the first EL element is referred to as a first compensation parameter,
a compensation parameter for compensating for the degradation of the second EL element is referred to as a second compensation parameter,
in the second inspection mode, the control unit:
causes the second EL element to emit light in order to operate the second EL element as a light-emitting element;
causes the first EL element to stop emitting light in order to operate the first EL element as a light-receiving element; and
as the first EL element receives the light emitted from the second EL element, generates the second compensation parameter in accordance with a current output from the first EL element, and
the control unit alternately switches between the first inspection mode and the second inspection mode in a period in which the first display region and the second display region face each other.

10. (canceled)

11. (canceled)

12. An inspection system, comprising:
a first display device including a first display region including a first EL element;
a second display device including a second display region including a second EL element;
a first control unit configured to control the first EL element; and
a second control unit configured to control the second EL element,
wherein the first control unit and the second control unit are communicably connected together, and
in an inspection mode for compensating for degradation of the first EL element,
the first control unit causes the first EL element to emit light in order to operate the first EL element as a light-emitting element,
the second control unit causes the second EL element to stop emitting light in order to operate the second EL element as a light-receiving element, and
as the second EL element receives the light emitted from the first EL element, the first control unit generates a compensation parameter, for compensating for the degradation of the first EL element, in accordance with a current output from the second EL element.

13. The inspection system according to claim 12,
wherein the first display device includes the first control unit, and
the second display device includes the second control unit.

14. A display device, comprising:
a first display device including a first display region including a first EL element;
a second display device including a second display region including a second EL element; and
a control unit configured to control the first EL element and the second EL element,
wherein, in an inspection mode for compensating for degradation of the first EL element, the control unit:
causes the first EL element to emit light in order to operate the first EL element as a light-emitting element;
causes the second EL element to stop emitting light in order to operate the second EL element as a light-receiving element; and
as the second EL element receives the light emitted from the first EL element, generates a compensation parameter, for compensating for degradation of the first EL element, in accordance with a current output from the second EL element.

15. The display device according to claim 14, further comprising
a mechanism configured to change a relative position of the second display region in relation to the first display region in order to cause the first display region and the second display region to face each other.

16. (canceled)

17. (canceled)

18. (canceled)

19. The display device according to claim 14,
wherein the control unit starts the inspection mode as soon as the first display region and the second display region face each other.

20. (canceled)

21. The display device according to claim 14,
wherein, in the inspection mode, the control unit:
derives luminance of the light, emitted from the first EL element, in accordance with the current output from the second EL element; and
generates the compensation parameter in accordance with the derived luminance.

22. The display device according to claim 14,
wherein, in the inspection mode, the control unit causes the first EL element to emit light so that the first display region displays an inspection pattern.

23. The display device according to claim 22,
wherein the inspection pattern is a linearly pattern in one dimension.

24. The display device according to claim 22,
wherein the inspection pattern is a dotted-line pattern in one dimension.

25. The display device according to claim 22,
wherein the inspection pattern is an island-shaped pattern having a plurality of bright regions scattered in two dimensions.

26. The display device according to claim 14,
wherein the inspection mode for compensating for the degradation of the first EL element is referred to as a first inspection mode,
an inspection mode for compensating for degradation of the second EL element is referred to as a second inspection mode,
the compensation parameter for compensating for the degradation of the first EL element is referred to as a first compensation parameter,
a compensation parameter for compensating for the degradation of the second EL element is referred to as a second compensation parameter,
in the second inspection mode, the control unit:
causes the second EL element to emit light in order to operate the second EL element as a light-emitting element;
causes the first EL element to stop emitting light in order to operate the first EL element as a light-receiving element; and
as the first EL element receives the light emitted from the second EL element, generates the second compensation parameter in accordance with a current output from the first EL element, and
the control unit alternately switches between the first inspection mode and the second inspection mode in a period in which the first display region and the second display region face each other.
